(19) United States
(12) Patent Application Publication
(10) Pub. No.: US 2026/0075779 A1
(43) Pub. Date: Mar. 12, 2026

(54) COOLING APPARATUS FOR POWER MODULE

(71) Applicants: HYUNDAI MOTOR COMPANY, SEOUL (KR); KIA CORPORATION, SEOUL (KR)

(72) Inventors: Sang Hun Lee, Hwaseong-si (KR); Hyong Joon Park, Hwaseong-si (KR); Se Heun Kwon, Hwaseong-si (KR)

(73) Assignees: HYUNDAI MOTOR COMPANY, SEOUL (KR); KIA CORPORATION, SEOUL (KR)

(21) Appl. No.: 19/205,142

(22) Filed: May 12, 2025

(30) Foreign Application Priority Data
Sep. 10, 2024 (KR) 10-2024-0122779

(51) Int. Cl. H05K 7/20

(52) U.S. Cl. CPC H05K 7/20927

(57) ABSTRACT

A cooling apparatus for a power module includes a manifold cover including an internal space in which a power module is installed, an inlet providing a passage for cooling fluid to flow into the internal space, and an outlet providing a passage for the cooling fluid to be discharged from the internal space and a valve member including a bimetal switch disposed on the manifold cover so that a flow rate of the cooling fluid is adjusted according to a temperature.

### CROSS REFERENCE TO RELATED APPLICATIONS

This application claims benefit of priority to Korean Patent Application No. 10-2024-0122779 filed on Sep. 10, 2024 in the Korean Intellectual Property Office, the disclosure of which is incorporated herein by reference in its entirety.

### BACKGROUND

### 1. Field The present disclosure relates to a cooling apparatus for a power module cooling a power module using a cooling fluid.

### 2. Description of Related Art

Power conversion devices of eco-friendly vehicle receive DC current from high-voltage batteries, convert the received DC current into AC current, and supply the AC current to motors, and control the torque and revolutions per minute (RPM) of motors by adjusting the magnitude and phase of the AC current. A power module of a power conversion device is a switching element converting DC current received from a high-voltage battery into AC current. If heat is generated during a switching process and the temperature rises above a certain level, damage may occur. Therefore, power modules of all power conversion devices require cooling, and as the cooling performance is improved, the current of higher specifications may be converted in the power module, so the performance of the power conversion device may also be improved.

The power module is applied to eco-friendly vehicles to control high voltage and high current. Accordingly, the amount of generated heat is very high, so appropriate cooling is required to maintain performance and durability. To this end, the power module may be cooled using a cooling fluid, or the waste heat of the power module is used for heating vehicles, etc.

### SUMMARY

A cooling apparatus for a power module may be subject to thermal shock (e.g., pumping out) due to temperature changes, and the thermal shock may affect the durability of the cooling apparatus for a power module.

An aspect of the present disclosure is to provide a cooling apparatus for a power module capable of reducing factors lowering durability (e.g., joint durability between the power module and an adjacent structure thereof) due to temperature changes.

According to an aspect of the present disclosure, a cooling apparatus for a power module includes a manifold cover including an internal space in which a power module is installed, an inlet providing a passage for cooling fluid to flow into the internal space, and an outlet providing a passage for the cooling fluid to be discharged from the internal space, and a valve member including a bimetal switch disposed on the manifold cover so that a flow rate of the cooling fluid is adjusted according to a temperature.

For example, the valve member may be configured so that a flow rate of the cooling fluid, when the temperature is higher than a reference temperature, is higher than a flow rate of the cooling fluid when the temperature is lower than the reference temperature.

For example, the valve member may be configured to be bent further when the temperature is lower than the reference temperature than when the temperature is higher than the reference temperature.

For example, the inlet may extend in a direction, perpendicular to a direction in which the cooling fluid flows in the internal space of the manifold cover, and the valve member may be configured to block a space between the internal space of the manifold cover and the inlet as the valve member is bent.

For example, the inlet, the valve member, and the outlet may overlap each other in the extending direction of the inlet, and an overlapping area of the valve member with respect to the inlet may be configured to decrease as the valve member is bent.

For example, the cooling apparatus may further include: a fin plate built into the manifold cover to contact the power module and having a plurality of cooling fins formed on a surface of the fin plate facing an internal surface of the manifold cover.

For example, the fin plate may include a mounting portion provided in a region, different from a region in which the plurality of cooling fins are formed, on the surface facing the internal surface of the manifold cover, and the valve member may be disposed in the mounting portion.

For example, the cooling apparatus may further include a guide wall configured to form a plurality of channels extending parallel to the flow direction in which the cooling fluid flows on the internal surface of the manifold cover.

For example, the valve member may be configured to block the plurality of channels when the temperature is higher than the reference temperature and to open the plurality of channels when the temperature is lower than the reference temperature.

For example, each of the plurality of cooling fins may extend in a direction, perpendicular to the flow direction in which the cooling fluid flows.

For example, the pin plate may include a first pin plate disposed on one surface of the power module and having a first flow hole, and a second pin plate disposed on the other surface of the power module and having a second flow hole, wherein the first flow hole and the second flow hole overlap each other.

For example, the power module may be a plurality of power modules arranged in the flow direction in which the cooling fluid flows.

For example, the manifold cover may include a first manifold cover disposed on a plurality of cooling fins of the first fin plate, and a second manifold cover disposed on a plurality of cooling fins of the second fin plate, wherein the first manifold cover and the second manifold cover are coupled to each other.

### BRIEF DESCRIPTION OF THE FIGURES

The and other aspects, features, and advantages of the present disclosure will be more clearly understood from the following detailed description, taken in conjunction with the accompanying diagrams, in which:

FIG. 1 is a diagram illustrating a cooling apparatus for a power module according to an embodiment of the present disclosure;

FIG. 2A is an assembly diagram of a cooling apparatus for a power module at high temperatures according to an embodiment of the present disclosure;

FIG. 2B is an assembly diagram of a cooling apparatus for a power module at low temperatures according to an embodiment of the present disclosure;

FIG. 3 is a diagram illustrating a cooling fin of a fin plate of a cooling apparatus for a power module according to an embodiment of the present disclosure;

FIG. 4 is a diagram illustrating a connection structure of a guide wall and a fin plate of a cooling apparatus for a power module according to an embodiment of the present disclosure; and

FIG. 5 is an assembly diagram illustrating a structure in which a coupling portion is further added to a manifold cover of a cooling apparatus for a power module according to an embodiment of the present disclosure.

### DETAILED DESCRIPTION

While the present disclosure may be modified in various ways and take on various alternative forms, specific embodiments thereof are illustrated in the diagrams and described in detail below. However, it should be understood that there is no intent to limit the present disclosure to the particular forms disclosed, but on the contrary, the present disclosure covers all modifications, equivalents, and alternatives falling within the spirit and scope of the present disclosure.

It will be understood that, although the terms “first,” “second,” etc. may be used herein to describe various elements, these elements should not be limited by these terms. These terms are only used to distinguish one element from another. For example, a first element could be termed a second element, and a second element could similarly be termed a first element without departing from the scope of the present disclosure. As used herein, the term “and/or” includes any and all combinations of one or more of the associated listed items.

The terms used herein to describe embodiments of the present disclosure is not intended to limit the scope of the present disclosure. The articles “a,” and “an” are singular in that they have a single referent, however the use of the singular form in the present document should not preclude the presence of more than one referent. In other words, elements of the present disclosure referred to in the singular may number one or more, unless the context clearly indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein including technical and scientific terms have the same meanings as understood by those skilled in the art to which the present disclosure pertains. Such terms as defined in generally used dictionaries should be construed to have the same meanings as those of the contexts of the related art, and unless clearly defined in the application, they should not be construed to have ideally or excessively formal meanings.

In this specification, vehicles (including electric vehicles) refer to a variety of vehicles that move transported objects, such as people, animals, or goods, from a starting point to a destination. These vehicles are not limited to vehicles that run on roads or tracks.

Hereinafter, embodiments of the present disclosure will be described with reference to the accompanying drawings.

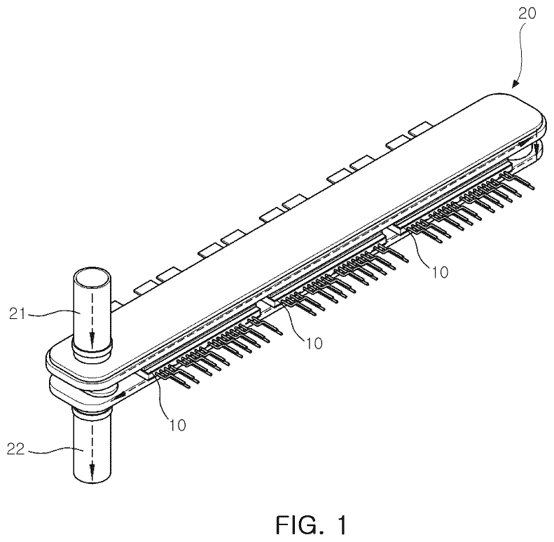

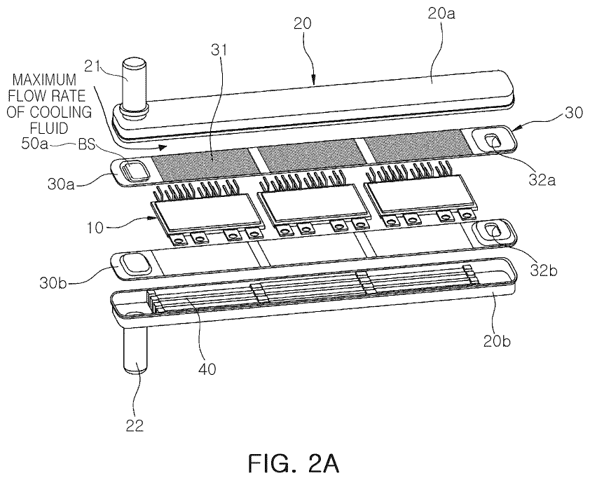

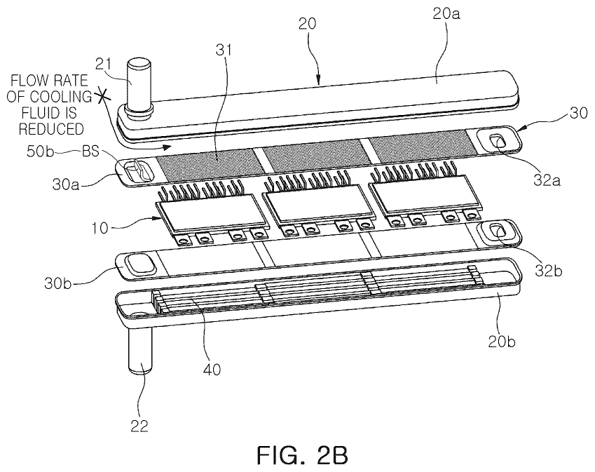

Referring to FIGS. 1, 2A, and 2B, a cooling apparatus for a power module according to an embodiment of the present disclosure may include a power module 10, a manifold cover 20, and valve members 50a and 50b.

The cooling apparatus for the power module may be installed in an eco-friendly vehicle. For example, the eco-friendly vehicle may include a hybrid vehicle (HEV), a plug-in hybrid vehicle (HEV), an electric vehicle (EV), a fuel cell electric vehicle (FCEV), etc., and may include a high-voltage battery and a motor.

The power module 10 may convert DC current received from an external high-voltage battery (e.g., inside an eco-friendly vehicle) into AC current and output the same to an external motor (e.g., inside the eco-friendly vehicle). The power module 10 may include an inverter converting DC current into AC current, and the inverter may include a plurality of switching elements. For example, the power module 10 may receive DC current through a plurality of (e.g., four) input terminals on one side and output AC current through a plurality of (e.g., 20) output terminals on the other side. For example, each of the plurality of switching elements may include a power semiconductor device (e.g., insulated gate bipolar transistor (IGBT), thyristor, etc.) and/or a diode. Depending on the design, the power module 10 may further include a converter or rectifier converting AC current based on regenerative braking in the motor into DC current.

The power module 10 may be a plurality of power modules 10 arranged in a flow direction (e.g., a horizontal direction) in which the cooling fluid flows. As the number of the plurality of power modules 10 greater, the total power capacity of the plurality of power modules 10 may increase. As the total power capacity of the power module 10 increases, the magnitude of current flowing to the input terminal and output terminal of the power module 10 may increase, the torque of the motor may become stronger, and the amount of heat generated by the power module 10 may also increase.

The manifold cover 20 may have an internal space in which the power module 10 is installed, an inlet 21 providing a passage through which a cooling fluid flows into the internal space, and an outlet 22 providing a passage through which the cooling fluid is discharged from the internal space. As the cooling fluid flows from the inlet 21 to the outlet 22 once, all the power modules 10 installed in the manifold cover 20 may be cooled once.

The internal space of the manifold cover 20 may expand or contract depending on the temperature, and the stress due to the expansion and contraction of the internal space of the manifold cover 20 may increase as a temperature change range widens. The stress may be a factor lowering the durability of the internal space of the manifold cover 20 (e.g., the joint durability for an adjacent structure of the power module 10).

When the temperature change range of the internal space of the manifold cover 20 narrows, the stress due to the temperature change of the internal space of the manifold cover 20 may decrease and the durability of the internal space of the manifold cover 20 may be improved. For example, the temperature change range may be affected by an external environment (e.g., the external weather, season, and region of the eco-friendly vehicle) and may be affected by the temperature of the cooling fluid. Since the temperature of the cooling fluid may also be affected by the external environment, a temperature change pattern of the internal space of the manifold cover 20 may be similar to a temperature change pattern of the cooling fluid. For example, the temperature of the cooling fluid may be high when the temperature of the internal space of the manifold cover 20 is high and may be low when the temperature of the internal space of the manifold cover 20 is low.

Therefore, when a flow rate of the cooling fluid varies depending on the temperature of the manifold cover 20, the amount of heat cooled by the cooling fluid in the internal space of the manifold cover 20 may vary depending on the temperature, and the temperature change range depending on the external environment of the internal space of the manifold cover 20 may be reduced.

The valve members 50a and 50b may include a bimetal switch BS disposed in the manifold cover 20 so that a flow rate of the cooling fluid is adjusted depending on the temperature. The bimetal switch BS may have a shape in which two metal plates having different coefficients of thermal expansion overlap each other, and an angle at which the bimetal switch BS is bent may vary depending on the temperature. Accordingly, the cooling apparatus for a power module according to an embodiment of the present disclosure may reduce the temperature change range depending on the external environment of the internal space of the manifold cover 20 and may reduce the factor lowering durability (e.g., joint durability for an adjacent structure of the power module 10) depending on the temperature change.

In addition, the bimetal switch BS of the valve members 50a and 50b may operate (e.g., be bent) without an external control signal (e.g., a signal from an electronic control unit in the eco-friendly vehicle) and may operate without an external power supply (e.g., power supply from a battery in the eco-friendly vehicle). That is, the cooling apparatus for a power module according to an embodiment of the present disclosure may control the flow rate of the cooling fluid according to the temperature even without a separate structure for controlling (and/or supplying power to) the valve members 50a and 50b, and thus costs associated with the separate structure may be reduced. For example, the bimetal switch BS may be manufactured according to a press mold.

Referring to FIG. 2A, when the temperatures of the internal space of the manifold cover 20 and the cooling fluid are higher (e.g., 65 degrees Celsius) than a reference temperature (e.g., room temperature, 25 degrees Celsius), the valve member 50a may open a space between the internal space of the manifold cover 20 and the inlet 21 so that the flow rate of the cooling fluid is maximized. Accordingly, the amount of heat cooled by the cooling fluid in the internal space of the manifold cover 20 may be relatively large.

Referring to FIG. 2B, when the temperatures of the internal space of the manifold cover 20 and the cooling fluid are lower (e.g., 31 40 degrees Celsius to 0 degrees Celsius) than the reference temperature (e.g., room temperature, 25 degrees Celsius), the valve member 50b may block at least a portion of the space between the internal space of the manifold cover 20 and the inlet 21 so that the flow rate of the cooling fluid is reduced. Accordingly, the amount of heat cooled by the cooling fluid in the internal space of the manifold cover 20 may be relatively small or none.

That is, the valve members 50a and 50b may be configured so that the flow rate of the cooling fluid when the temperatures of the internal space of the manifold cover 20 and the cooling fluid are higher than the reference temperature is higher than the flow rate of the cooling fluid when the temperatures thereof are lower than the reference temperature. Accordingly, the temperature change range of the internal space of the manifold cover 20 according to the external environment (e.g., the external weather, season, and region of the eco-friendly vehicle) may be narrowed.

For example, the valve members 50a and 50b may be configured to be bent further when the temperatures of the internal space of the manifold cover 20 and the cooling fluid are lower than the reference temperature (e.g., room temperature, 25 degrees) than when they are higher than the reference temperature. The valve members 50a and 50b may operate (e.g., be bent) without an external control signal (e.g., a signal from the electronic control unit in the eco-friendly vehicle) and may operate without an external power supply (e.g., power supply from the battery in the eco-friendly vehicle). That is, the cooling apparatus for a power module according to an embodiment of the present disclosure may control the flow rate of the cooling fluid according to the temperature even without a separate structure controlling the bending of the valve members 50a and 50b (and/or supplying power), and thus the costs associated with the separate structure may be reduced.

For example, the inlet 21 may extend in a direction (e.g., a vertical direction), perpendicular to the flow direction in which the cooling fluid flows in the internal space of the manifold cover 20, and the inlet 21, the valve members 50a and 50b, and the outlet 22 may overlap each other in the extending direction (e.g., the vertical direction) of the inlet 21. The valve members 50a and 50b may be configured to block the space between the internal space of the manifold cover 20 and the inlet 21 when the valve members 50a and 50b are bent, and the overlapping area of the valve members 50a and 50b with respect to the inlet 21 may be configured to decrease as the valve members 50a and 50b are bent. As the overlapping area decreases, the valve members 50a and 50b may reduce the flow rate of the cooling fluid more significantly. The inlet 21 and the outlet 22 may be configured in a serial structure, and although the diagram illustrates that the cooling fluid flows in the vertical direction, the flow direction may be the opposite and is not limited to the vertical direction.

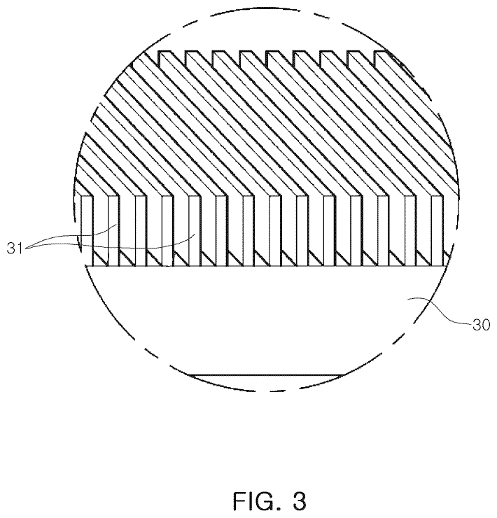

Referring to FIGS. 2A, 2B, and 3, the cooling apparatus for a power module according to an embodiment of the present disclosure may further include a fin plate 30 which is built into the manifold cover 20, is in contact with the power module 10, and has a plurality of cooling fins 31 formed on a surface of the fin plate 30 facing the internal surface of the manifold cover 20.

Since the fin plate 30 is in contact with the power module 10, the fin plate 30 may absorb heat generated by the power module 10. Since the plurality of cooling fins 31 may increase a contact area between the fin plate 30 and the cooling fluid, the cooling efficiency of the cooling fluid may be increased. The cooling apparatus for a power module according to an embodiment of the present disclosure may reduce the factor lowering the joint durability between the fin plates 30 of the power module 10 due to a significant temperature change in the internal space of the manifold cover 20.

For example, the fin plate 30 may include a first fin plate 30a disposed on one surface (e.g., an upper surface) of the power module 10 and having a first flow hole 32a and a second fin plate 30b disposed on the other surface (e.g., a lower surface) of the power module 10 and having a second flow hole 32b. Accordingly, the power module 10 may generate heat through both surfaces. The first fin plate 30a and the second fin plate 30b may have the same shape and may be arranged to be symmetrical with respect to each other but are not limited thereto.

The manifold cover 20 may include a first manifold cover 20a disposed on a plurality of cooling fins 31 of the first fin plate 30a and a second manifold cover 20b disposed on a plurality of cooling fins (not illustrated) of the second fin plate 30b. The first manifold cover 20a and the second manifold cover 20b may have the same shape and may be arranged to be symmetrical with respect to each other but is not limited thereto.

The first fin plate 30a may be disposed between the first manifold cover 20a of the manifold cover 20 and the power module 10, and the second fin plate 30b may be disposed between the second manifold cover 20b of the manifold cover 20 and the power module 10. As the first manifold cover 20a and the second manifold cover 20b are combined, the first fin plate 30a and the second fin plate 30b may be closely attached to both sides of the power module 10. For example, the edge of the first manifold cover 20a may be combined with the first fin plate 30a by at least one of welding, bonding, and bolting, and the edge of the second manifold cover 20b may be combined with the second fin plate 30b by at least one of welding, bonding, and bolting.

The first flow hole 32a and the second flow hole 32b may overlap each other in the vertical direction, and the cooling fluid may pass through the first flow hole 32a and the second flow hole 32b. Accordingly, as the cooling fluid flows once from the inlet 21 to the outlet 22, each of the both sides of the power module 10 may be cooled once.

The fin plate 30 may include a mounting portion provided in a region (e.g., both end regions) different from a region (e.g., a central region) in which a plurality of cooling fins 31 are formed on a surface facing the internal surface of the manifold cover 20, and the valve members 50a and 50b may be arranged on the mounting portion. For example, the mounting portion may be formed concavely or sunken in a shape substantially identical to that of the valve members 50a and 50b and may fix the position of the valve members 50a and 50b.

Alternatively, the mounting portion provided in a different region (e.g., both end regions) of the fin plate 30 may be bonded to a portion of the valve members 50a and 50b through an adhesive member or may be coupled to a portion of the valve members 50a and 50b by mechanical coupling (e.g., a bolt coupling, screw coupling, a stud coupling, etc.).

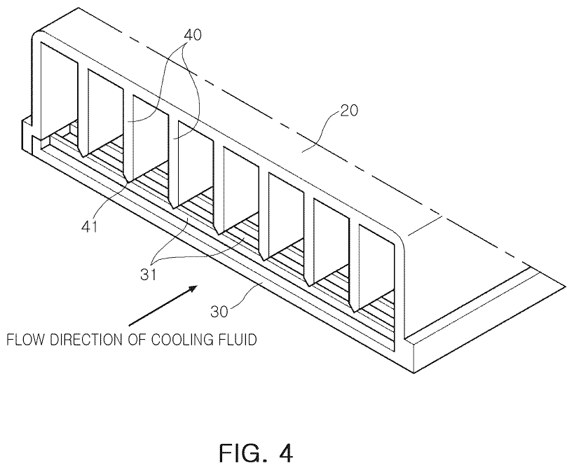

Referring to FIGS. 2A, 2B, and 4, the cooling apparatus for a power module according to an embodiment of the present disclosure may further include a guide wall 40 configured to form a plurality of channels extending in parallel in the flow direction (e.g., the horizontal direction) in which the cooling fluid flows from the internal surface of the manifold cover 20. The cooling fluid may pass through the plurality of channels. Depending on the design, the plurality of channels may be connected to each other in a zigzag shape, and the cooling fluid may further circulate through the plurality of channels as if in a turbulent flow.

The valve members 50a and 50b may be configured to block the plurality of channels when the temperatures of the internal space of the manifold cover 20 and the cooling fluid are higher than the reference temperature (e.g., room temperature, 25 degrees Celsius) and to open the plurality of channels when they are lower than the reference temperature. Since the plurality of channels of the guide wall 40 are a portion of the internal space of the manifold cover 20, the cooling performance of the cooling fluid may be adjusted as the valve members 50a and 50b block the plurality of channels of the guide wall 40.

For example, the guide wall 40 may be formed to contact the cooling fin 31 of the fin plate 30, and a main flow of the cooling fluid may be formed through the cooling fin 31. The guide wall 40 may be disposed on the first manifold cover 20a and may contact the plurality of cooling fins 31 of the first fin plate 30a and may be disposed on the second manifold cover 20b and may contact the plurality of cooling fins (not illustrated) of the second fin plate 30b. The guide wall (not illustrated) disposed on the first manifold cover 20a and the guide wall 40 disposed on the second manifold cover 20b may be arranged to be point-symmetrical with respect to each other in the vertical direction but is not limited thereto.

Referring to FIGS. 3 and 4, each of the plurality of cooling fins 31 may extend in a direction, perpendicular to the flow direction in which the cooling fluid flows. Accordingly, the cooling fluid may be cooled by a jet impingement principle on the plurality of cooling fins 31, while flowing through the plurality of channels of the guide wall 40. The jet impingement principle may obtain a locally high heat transfer effect for each point of the fin plate 30. The plurality of cooling fins 31 are not limited to the structure for the jet impingement principle and may have a pin-fin structure or a wave fin structure depending on the design.

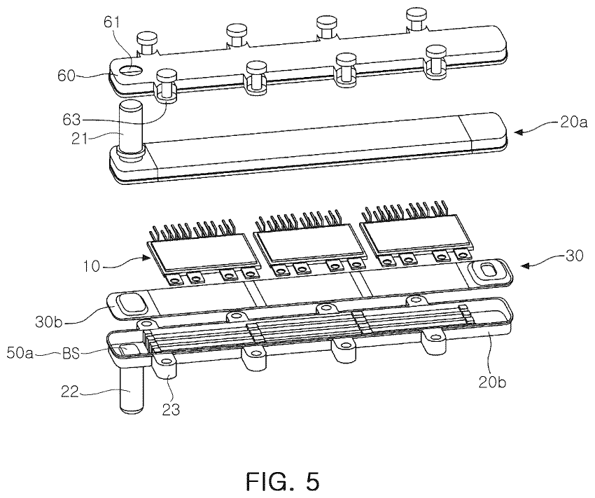

Referring to FIG. 5, the first manifold cover 20a may include a coupling portion 60, the coupling portion 60 may include a first coupling portion 63, and the second manifold cover 20b may include a second coupling portion 23. By coupling the first coupling portion 63 and the second coupling portion 23 to each other, the coupling portion 60 may press the first manifold cover 20a, and the first manifold cover 20a and the second manifold cover 20b may be more firmly coupled to each other. For example, the first coupling portion 63 and the second coupling portion 23 may be coupled by mechanical coupling (e.g., bolt coupling, screw coupling, stud coupling, etc.) but are not limited thereto.

For example, the coupling portion 60 may be coupled to the first manifold cover 20a by the inlet 21 penetrating a through-hole 61. The first coupling portion 63 may be a plurality of first coupling portions 63 arranged at equal intervals along the edge of the coupling portion 60, and the second coupling portion 23 may be a plurality of second coupling portions 23 arranged at equal intervals along the edge of the second manifold cover 20b.

Meanwhile, unlike the cooling apparatus for a power module of FIG. 2A, the valve member 50a may selectively block the space between the internal space of the second manifold cover 20b and the outlet 22 depending on the temperature. The position of the valve member 50a is not limited to the inlet 21 or the outlet 22 and may be disposed anywhere in the cooling apparatus for a power module in which the flow rate of the cooling fluid may be adjusted according to the temperature.

The cooling apparatus for a power module according to an embodiment of the present disclosure may reduce the factor lowering the durability (e.g., joint durability between the power module and an adjacent structure) due to a temperature change, and since the flow rate of the cooling fluid may be adjusted according to the temperature even without a separate structure controlling (and/or supplying power to) the valve member, the costs associated with the separate structure may be reduced.

While embodiments have been illustrated and described above, it will be apparent to those skilled in the art that modifications and variations could be made without departing from the scope of the present disclosure as defined by the appended claims.

1. A cooling apparatus for a power module, the cooling apparatus comprising:
a manifold cover including an internal space having a power module, an inlet providing a passage for cooling fluid to flow into the internal space, and an outlet providing a passage for the cooling fluid to be discharged from the internal space; and
a valve member including a bimetal switch disposed on the manifold cover configured to adjust a flow rate of the cooling fluid according to a temperature.

2. The cooling apparatus of claim 1, wherein the valve member is configured so that a flow rate of the cooling fluid, when the temperature is higher than a reference temperature, is higher than a flow rate of the cooling fluid when the temperature is lower than the reference temperature.

3. The cooling apparatus of claim 2, wherein the valve member is configured to be bent further when the temperature is lower than the reference temperature than when the temperature is higher than the reference temperature.

4. The cooling apparatus of claim 3, wherein:
the inlet extends in a direction perpendicular to a direction in which the cooling fluid flows in the internal space of the manifold cover; and
the valve member is configured to block a space between the internal space of the manifold cover and the inlet as the valve member is bent.

5. The cooling apparatus of claim 4, wherein the inlet, the valve member, and the outlet overlap each other in the extending direction of the inlet, and an overlapping area of the valve member with respect to the inlet is configured to decrease as the valve member is bent.

6. The cooling apparatus of claim 1, further comprising a fin plate built into the manifold cover configured to contact the power module and having a plurality of cooling fins formed on a surface of the fin plate facing an internal surface of the manifold cover.

7. The cooling apparatus of claim 6, wherein the fin plate includes a mounting portion provided in a region, different from a region in which the plurality of cooling fins are formed, on a surface facing the internal surface of the manifold cover, and the valve member is disposed in the mounting portion.

8. The cooling apparatus of claim 6, further comprising a guide wall forming a plurality of channels extending parallel to a flow direction in which the cooling fluid flows on the internal surface of the manifold cover.

9. The cooling apparatus of claim 8, wherein the valve member is configured to block the plurality of channels when the temperature is higher than the reference temperature, and to open the plurality of channels when the temperature is lower than the reference temperature.

10. The cooling apparatus of claim 9, wherein each of the plurality of cooling fins extends in a direction perpendicular to the flow direction in which the cooling fluid flows.

11. The cooling apparatus of claim 6, wherein the fin plate includes:
a first fin plate disposed on one surface of the power module and having a first flow hole; and
a second fin plate disposed on an other surface of the power module and having a second flow hole;
wherein the first flow hole and the second flow hole overlap each other.

12. The cooling apparatus of claim 11, wherein the power module comprises a plurality of power modules arranged in the flow direction in which the cooling fluid flows.

13. The cooling apparatus of claim 11, wherein the manifold cover includes:
a first manifold cover disposed on a plurality of cooling fins of the first fin plate; and
a second manifold cover disposed on a plurality of cooling fins of the second fin plate;
wherein the first manifold cover and the second manifold cover are coupled to each other.
